(19) United States
(12) Patent Application Publication
(10) Pub. No.: US 2026/0122887 A1
(43) Pub. Date: Apr. 30, 2026

(54) Semiconductor Device and Method of Fabricating the Same

(71) Applicant: Fujian Jinhua Integrated Circuit Co., Ltd., Quanzhou City (CN)

(72) Inventors: Li-Wei Feng, Quanzhou City (CN); Yidan Zhang, Quanzhou City (CN); Jianshan Wu, Quanzhou City (CN)

(73) Assignee: Fujian Jinhua Integrated Circuit Co., Ltd., Quanzhou City (CN)

(21) Appl. No.: 19/189,160

(22) Filed: Apr. 24, 2025

(30) Foreign Application Priority Data
Oct. 31, 2024 (CN) 202411547295.4

(51) Int. Cl. H10B 12/00

(52) U.S. Cl. CPC H10B 12/50; H10B 12/09; H10B 12/315; H10B 12/482

(57) ABSTRACT

The present invention discloses a semiconductor device and a method of fabricating the same, and the semiconductor device includes a substrate, a bit line structure, a gate structure, an etching stop layer and an interlayer dielectric layer. The substrate includes a first region and a second region. The bit line structure is disposed on the substrate, within the first region. The gate structure is disposed on the substrate, within the second region. The etching stop layer is disposed on the substrate and overlays a top surface and a sidewall of the bit line structure, and a sidewall of the gate structure. The interlayer dielectric layer overlays the bit line structure and the gate structure, wherein the interlayer dielectric layer physically contacts the etching stop layer that overlays the top surface of the bit line structure, and a top surface of the gate structure.

### CROSS REFERENCE TO RELATED APPLICATION

This application claims the benefit of Chinese Patent Application No. 202411547295.4 filed on Oct. 31, 2024, which is incorporated herein by reference.

### BACKGROUND OF THE INVENTION

### 1. Field of the Invention

The present invention relates to a semiconductor device and the method for fabricating the same, in particular to a semiconductor memory device and the method for fabricating the same.

### 2. Description of the Prior Art

With the trend of miniaturization of various electronic products, the design of semiconductor memory devices must meet the requirements of high integration and high density. For a dynamic random access memory (DRAM) having recessed gate structures, because the carrier channel of which is relatively long in the same semiconductor substrate compared with that of the DRAM without recessed gate structures, the leakage current from the capacitor structure in the DRAM can be reduced. Therefore, the DRAM having recessed gate structures has gradually replaced DRAM having planar gate structures under the current mainstream development trend. Generally, the DRAM having recessed gate structure is constructed by a large number of memory cells which are arranged to form an array area, and each of the memory cells can be used to store information. Each memory cell may include a transistor element and a capacitor element connected in series, which is configured to receive voltage information from word lines (WL) and bit lines (BL). In order to fulfill the requirements of advanced products, the density of memory cells in the array area must be further increased, which increases the difficulty and complexity of related fabricating processes and designs. Therefore, the present technology needs further improvement to effectively improve the efficiency and reliability of related memory devices.

### SUMMARY OF THE INVENTION

One of the objectives of the present disclosure provides a semiconductor device and a method of fabricating the same, where an etching stop layer is formed to have various covering degrees within different regions, and/or a process such as a planarization process or an etching back process is performed to thin down the thickness of a cover layer within a specific region, thereby improving the possible height-difference between various regions of the semiconductor device. Accordingly, the structural reliability of the semiconductor device has been promoted, and the semiconductor device of the present disclosure is allowable to gain better performance and operation thereby.

To achieve the purpose described above, one embodiment of the present disclosure provides a semiconductor device including a substrate, a bit line structure, a gate structure, an etching stop layer and an interlayer dielectric layer. The substrate includes a first region and a second region. The bit line structure is disposed on the substrate, within the first region. The gate structure is disposed on the substrate, within the second region. The etching stop layer is disposed on the substrate and overlays a top surface and a sidewall of the bit line structure, and a sidewall of the gate structure. The interlayer dielectric layer overlays the bit line structure and the gate structure, wherein the interlayer dielectric layer physically contacts the etching stop layer that overlays the top surface of the bit line structure, and a top surface of the gate structure.

To achieve the purpose described above, one embodiment of the present disclosure provides a method of fabricating a semiconductor device including the following steps. Firstly, a substrate is provided, and the substrate includes a first region and a second region. The bit line structure is formed on the substrate, within the first region. The gate structure is formed on the substrate, within the second region. The etching stop layer is formed to overlay a top surface and a sidewall of the bit line structure, and a sidewall of the gate structure. The interlayer dielectric layer is formed to overlay the bit line structure and the gate structure, wherein the interlayer dielectric layer physically contacts the etching stop layer that overlays the top surface of the bit line structure, and a top surface of the gate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present invention. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 2 are schematic diagrams illustrating a semiconductor device according to a first embodiment in the present disclosure, wherein:

FIG. 1 shows a schematic cross-sectional view of a semiconductor device; and

FIG. 2 shows another schematic cross-sectional view of a semiconductor device.

FIG. 3 to FIG. 10 are schematic diagrams illustrating a fabricating method of a semiconductor device according to one embodiment in the present disclosure, wherein:

FIG. 3 shows a schematic cross-sectional view of a semiconductor device after forming a first semiconductor layer;

FIG. 4 shows a schematic cross-sectional view of a semiconductor device after forming a bit line opening;

FIG. 5 shows a schematic cross-sectional view of a semiconductor device after forming a second semiconductor layer;

FIG. 6 shows a schematic cross-sectional view of a semiconductor device after forming a covering material layer;

FIG. 7 shows a schematic cross-sectional view of a semiconductor device after forming an etching stop material layer;

FIG. 8 shows a schematic cross-sectional view of a semiconductor device after performing a planarization process;

FIG. 9 shows a schematic cross-sectional view of a semiconductor device after forming an etching stop layer; and

FIG. 10 shows a schematic cross-sectional view of a semiconductor device after forming an interlayer dielectric layer.

FIG. 11 to FIG. 12 are schematic diagrams illustrating a fabricating method of a semiconductor device according to another embodiment in the present disclosure, wherein:

FIG. 11 shows a schematic cross-sectional view of a semiconductor device after performing an etching back process; and

FIG. 12 shows a schematic cross-sectional view of a semiconductor device after forming an etching stop layer.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

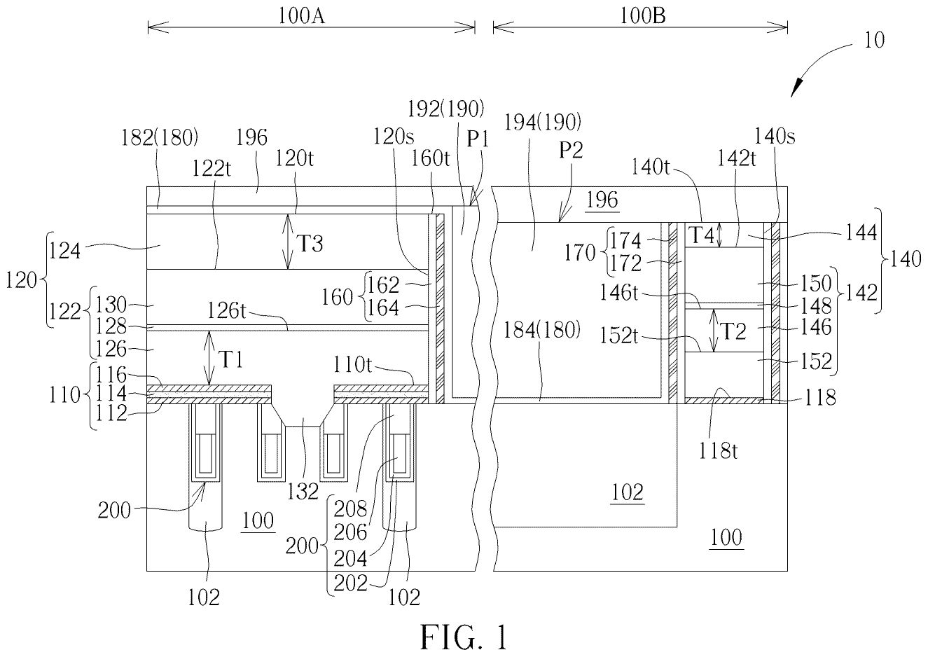

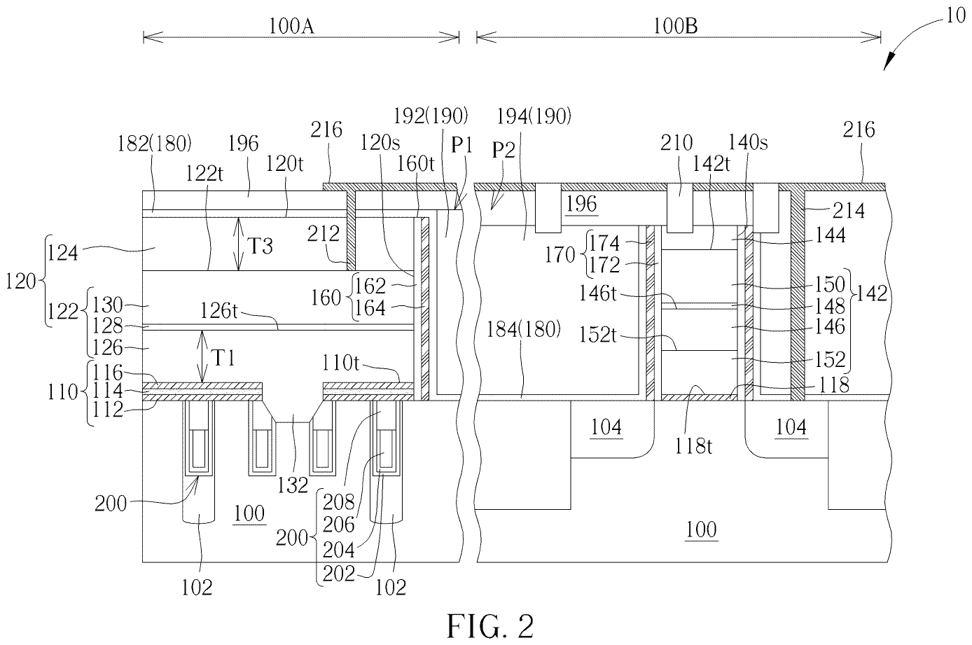

Please refer to FIG. 1 to FIG. 2, which illustrate schematic diagrams of a semiconductor device 10 according to a preferable embodiment in the present disclosure. Firstly, as shown in FIG. 1, the semiconductor device 10 includes a substrate 100, a bit line structure 120, a gate structure 140, an etching stop layer 180 and an interlayer dielectric layer 186. The substrate 100 for example includes a silicon substrate, a silicon containing substrate (such as SiC or SiGe), or a silicon-on-insulator (SOI) substrate, and at least two regions are defined on the substrate 100, for example being a first region 100A having a relative higher component-integrity and a second region 100B having a relative lower component-integrity. The first region 100A is for example configured as a memory cell region of the semiconductor device 10, and the second region 100B is for example configured as a periphery region of the semiconductor device 10, with the second region 100B being disposed for example at a side of the first region 100A, as shown in FIG. 1, but not limited thereto. Also, at least one shallow trench isolation (STI) 102 is formed in the substrate 100, to define a plurality of active areas (AAs) on the substrate 100.

The bit line structure 120 and the gate structure 140 are both disposed on the substrate 100, with the bit line structure 120 being disposed within the first region 100A, and with the gate structure 140 being disposed within the second region 100B. The etching stop layer 180 is also disposed on the substrate 100, wherein, the etching stop layer 182 disposed within the first region 100A entirely overlays the bit line structure 120 and the substrate 100, for example simultaneously covering the top surface 120t and the sidewall 120s of the bit line structure 120, and the etching stop layer 184 disposed within the second region 100B overlays the sidewall 140s of the gate structure 140 and the substrate 100. The interlayer dielectric layer 196 is disposed on the etching stop layer 180, entirely overlaying the bit line structure 120 and the gate structure 140. It is noted that the etching stop layer 184 disposed within the second region 100B does not overlay the top surface 140t of the gate structure 140, so that, the interlayer dielectric layer 196 will physically contact the top surface 140t of the gate structure 140, as well as the etching stop layer 182 covered on the top surface 120t of the bit line structure 120. Accordingly, the bit line structure 120 disposed within the first region 100A and the gate structure 140 disposed within the second region 100B will both gain improved structural stability, and the semiconductor device 10 will therefore obtain better function and performance.

In one embodiment, the bit line structure 120 precisely includes a first conductive layer 122 and a first cover layer 124 stacked sequentially on a dielectric layer 110, with the first cover layer 124 for example includes an insulating material like silicon oxide, silicon nitride, or silicon oxynitride. The first conductive layer 122 preferably includes a multilayer structure, for example including a semiconductor layer 126 (for example including a semiconductor material such as doped polysilicon material), a barrier layer 128 (for example including a conductive barrier material such as titanium and/or titanium nitride), and a metal layer 130 (for example including a low-resistant conductive material like copper, aluminum, or tungsten) stacked from bottom to top on the top surface 110t of the dielectric layer 110, but not limited thereto. Furthermore, at least one bit line contact (BLC) 132 is further disposed under the bit line structure 120, with the at least one bit line contact 132 penetrating through the dielectric layer 110 and partially extending into the substrate 100 within the first region 110A, between two adjacent buried gate structures 200, so that, the bit line structure 120 is allowable to be electrically connected to a corresponding active areas within the first region 100A via the at least one bit line contact 132 disposed underneath. Preferably, the semiconductor layer 126 of the first conductive layer 122 and the bit line contact 132 are for example monolithic, and which may include the same semiconductor material like doped polysilicon material, but not limited thereto. The dielectric layer 110 for example includes a composite structure for example including an oxide layer 112—a nitride layer 114—an oxide layer 116 (ONO) structure, but is not limited thereto. Also, a plurality of buried gate structures 200 is disposed in the substrate 100, under the dielectric layer 110, and each further includes an interface layer 202, a gate dielectric layer 204, a gate electrode 206 and a cover layer 208 stacked in sequence, but not limited thereto.

On the other hand, the gate structure 140 precisely includes a second conductive layer 142 and a second cover layer 144 stacked in sequence on the gate dielectric layer 118. The second cover layer 144 for example includes an insulating material like silicon oxide, silicon nitride, or silicon oxynitride, and the second conductive layer 142 preferably includes a multilayer structure for example including a bottom semiconductor layer 152 (for example including a semiconductor material like doped polysilicon or doped amorphous silicon), a top semiconductor layer 146 (for example including a semiconductor material like doped polysilicon or doped amorphous silicon), a barrier layer 148 (for example including a conductive barrier material like tantalum and/or tantalum nitride), and a metal layer 150 (for example including a low-resistant metal like tungsten, aluminum or copper) stacked in sequence on a top surface 118t of the gate dielectric layer 118. In one embodiment, the second cover layer 144 and the first cover layer 124 preferably include the same insulating material, the metal layer 150 of the second conductive layer 142 and the metal layer 130 of the first conductive layer 122 preferably include the same metal material, the barrier layer 148 of the second conductive layer 142 and the barrier layer 128 of the first conductive layer 122 preferably include the same conductive barrier material, and the top semiconductor layer 146 of the second conductive layer 142 and the semiconductor layer 126 of the first conductive layer 122 preferably include the same semiconductor material, but not limited thereto. In another embodiment, the gate dielectric layer 118, and the oxide layer 112 of the dielectric layer 110 preferably include the same material in the same thickness, but not limited thereto.

It is noted that, while a plane (namely the top surface 118t of the gate dielectric layer 118) of the second conductive layer 142 within the second region 100B is lower than a plane of the first conductive layer 122 within the first region 100A, the top surface 142t of the second conductive layer 142 is higher than the top surface 122t of the first conductive layer 122 due to additionally arranging the bottom semiconductor layer 152 within in the second conductive layer 142. Also, the top surface 126t of the semiconductor layer 126 within the first conductive layer 122 is preferably higher than the top surface 152t of the bottom semiconductor layer 152 within the second conductive layer 142, and a thickness T2 of the top semiconductor layer 146 is preferably the same as a thickness T1 of the semiconductor layer 126 over the dielectric layer 110, but not limited thereto. Furthermore, since a thickness T3 of the first cover layer 124 disposed over the first conductive layer 122 is larger than a thickness T4 of the second cover layer 144 disposed over the second conductive layer 142, the top surface (namely the top surface 140t of the gate structure 140) of the second cover layer 144 is lower than the top surface (the top surface 120t of the bit line structure 120) of the first cover layer 124.

Further in view of FIG. 1, the semiconductor device 10 further includes an insulating layer 190 disposed on the substrate 100, the bit line spacer 160 disposed on the sidewall 120s of the bit line structure 120, and a gate spacer 170 disposed on the sidewall 140s of the gate structure 140. The insulating layer 190 is for example disposed between the bit line structure 120 and the gate structure 140. The insulating layer 190 further includes an insulating layer 192 disposed within the first region 100A and an insulating layer 194 disposed within the second region 100B, with the insulating layer 192 only overlaying the etching stop layer 182 disposed over the bit line spacer 160, to obtain a first plane P1 being coplanar with the etching stop layer 182 covered on the top surface 120t of the bit line structure 120, and with the insulating layer 194 entirely overlaying the etching stop layer 184 within the second region 100B, to obtain a second plane P2 being coplanar with the etching stop layer 184, and the top surface 140t of the gate structure 140. That is, the top surface of the insulating layer 192 disposed within the first region 100A and the top surface of the insulating layer 194 disposed within the second region 100B are in different heights, and the first plane P1 within the first region 100A is preferably higher than the second plane P2 within the second region 100B.

The bit line spacer 160 is for example disposed between the bit line structure 120 and the etching stop layer 182 within the first region 100A, and which may further include a spacer 162 (for example including an insulating material like silicon nitride or silicon carbonitride), and a spacer 164 (for example including an insulating material like silicon oxide or silicon oxynitride) stacked in sequence on the sidewall 120s of the bit line structure 120, but not limited thereto. The etching stop layer 182 disposed within the first region 100A entirely overlays the bit line spacer 160, to physically contact the top surface 160t of the bit line spacer 160. The gate spacer 170 is for example disposed between the gate structure 140 and the etching stop layer 184 within the second region 100B, and which may further include a spacer 172 (for example including an insulating material like silicon nitride or silicon carbonitride), and a spacer 174 (for example including an insulating material like silicon oxide or silicon oxynitride) stacked in sequence on the sidewall 140s of the gate structure 140, but not limited thereto. In one embodiment, the spacer 162 of the bit line spacer 160 and the spacer 172 of the gate spacer 170 preferably include the same material in the same thickness with each other, and the spacer 164 of the bit line spacer 160 and the spacer 174 of the gate spacer 170 preferably also include the same material in the same thickness with each other, but not limited thereto.

Through these arrangements, the semiconductor device 10 of the present embodiment will be configure as a dynamic random access memory (DRAM) device, with the buried gate structures 200 and the bit line structure 120 within the first region 100A respectively serving as the buried word lines (WLs) and the bit line (BL) of the semiconductor device 10 for receiving or transmitting the required voltage signals from the substrate 100. According to the semiconductor device 10 of the present embodiment, due to additionally arranging the bottom semiconductor layer 152 in the second region 100B, the second conductive layer 142 of the gate structure 140 within the second region 100B is higher than first conductive layer 122 within the first region 100A. However, through arranging a thinner second cover layer 144 on the second conductive layer 142, the top surface (namely the top surface 140t of the gate structure 140) of the second cover layer 144 is lower than the top surface (namely, the top surface 120t of the bit line structure 120) of the first cover layer 124, and the etching stop layer 184 disposed within the second region 100B does not overlay the top surface of the second cover layer 144. Accordingly, the top surface 140t of the gate structure 140 within the second region 100B is lower than the top surface 120t of the bit line structure 120 within the first region 100A, and the interlayer dielectric layer 196 disposed thereon will physically contact the top surface 140t of the gate structure 140, and the etching stop layer 182 covered on the top surface 120t of the bit line structure 120. In this way, the bit line structure 120 and the gate structure 140 respectively disposed within the first region 100A and the second region 100B will both gain the improved structural reliability, and the semiconductor device 10 may achieve better performance and operation thereby.

Additionally, a plurality of plugs 212, 214 electrically connected to the bit line structure 120 and the gate structure 140, respectively, and a metal wire 216 connected to the plugs 212, 214 may be further disposed on the semiconductor device 10. Precisely speaking, as shown in FIG. 2, after forming the semiconductor device 10 as shown in FIG. 1, the plug 212 is disposed within the first region 100A and the plug 214 is disposed within the second region 100B, respectively, and the metal wire 216 is disposed both within the first region 100A and the second region 100B. The plug 212 in the first region 100A penetrates through the interlayer dielectric layer 196, the etching stop layer 182 and the first cover layer 124 to physically contact the first conductive layer 122 of the bit line structure 120, with the plug 212 being electrically connected to the bit line structure 120. The plug 214 in the second region 100B penetrates through the interlayer dielectric layer 196, the insulating layer 194 and the etching stop layer 182, to physically contact a doped region 104 disposed at two sides of the gate structure 140, with the plug 214 being electrically connected to the doped region 104 at the two sides of the gate structure 140.

It is noted that a plurality of insulating structures 210 each penetrating through the metal wire 216 and the interlayer dielectric layer 196 and extending into the insulating layer 194, the second cover layer 144 or the etching stop layer 184, is further disposed on the semiconductor device 10, such that the metal wire 216 in the second region 100B will be divided into a plurality of fragments. Accordingly, the fragments of the metal wire 216 are alternately arranged with the insulating structures 210 in the horizontal direction, so as to serve as metal lines for electrically connecting to various elements. In one embodiment, the insulating structures 210 for example includes an insulating material like silicon nitride or silicon carbonitride, and the plugs 212, 214 and the metal wire 216 for example includes a low-resistance metal material like aluminum, titanium, copper or tungsten, and preferably includes tungsten, but not limited thereto. Thus, a first layer interconnection (MO interconnection) for electrically connecting to the bit line structure 120 and the gate structure 140 is therefore formed, through arranging the plugs 212, 214 and the metal wire 216, and which can be effectively isolated from the metal wire 216 disposed on the gate structure 140 through arranging the insulating structure 210, avoiding the possible short-circuit issue, and further improving the operation of the semiconductor device 10 in the present embodiment.

In order to make people skilled in the art of the present disclosure easily understand the semiconductor device 10 of the present disclosure, the fabricating method of the semiconductor device 10 in the present disclosure will be further described below.

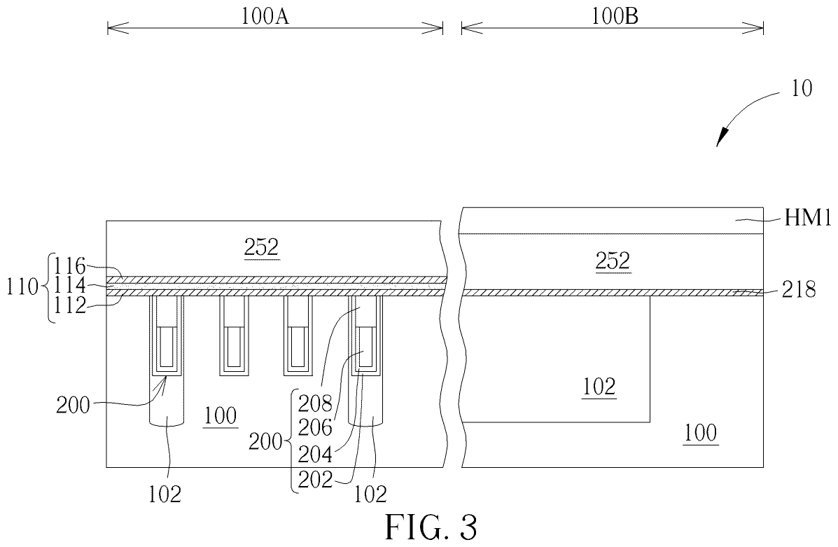

Please refer to FIG. 3 to FIG. 10, illustrating schematic diagrams of a fabricating method of the semiconductor device 10 according to the preferably embodiment in the present disclosure.

Firstly, as shown in FIG. 3, a substrate 100 is provided, and the shallow trench isolation 102 is formed in the substrate 100, within the first region 100A and the second region 100B, to define the active areas within the substrate 100. In one embodiment, the formation of the shallow trench isolation 102 is for example carried out by firstly forming a plurality of trenches (not shown in the drawings) in the substrate 100 through an etching process, followed by forming an insulating material in the trenches (for example including a material like silicon oxide or silicon oxynitride), but not limited thereto. Next, the buried gate structures 200 within the substrate 100 and the dielectric layer 110 overlaying the substrate 100 are sequentially formed in the first region 100A, and a gate dielectric material layer 218 is formed in the second region 100B. In one embodiment, the formation of the buried gate structures 200 is carried out but not limited to the following steps, including firstly forming a plurality trenches (not shown in the drawings) across the active areas and the shallow trench isolations, and sequentially forming an interface layer 202 entirely covering the surface of each of the trenches, a gate dielectric layer 204 covering the surface of the bottom of each trench, a gate electrode 206 filled in the bottom of each trench, and the cover layer 208 filled in the top of each trench, but not limited thereto.

The dielectric layer 110 (including the oxide layer 112—the nitride layer 114—the oxide layer 116 structure) overlays the top surface of the substrate 100 in the first region 100A, and the gate dielectric material layer 218 overlays the top surface of the substrate 100 in the second region 100B. The gate dielectric material layer 218 for example includes an insulating material like silicon oxide or silicon oxynitride, and preferably includes the same material and the same thickness as those of the oxide layer 112 of the dielectric layer 110, but not limited thereto. In one embodiment, the formations of the dielectric layer 110 and the gate dielectric material layer 218 include but not limited to the following steps. Firstly, a first oxide material layer (not shown in the drawings), a nitride material layer (not shown in the drawings), and a second oxide material layer (not shown in the drawings) are sequentially formed on the substrate 100 both within the first region 100A and the second region 100B, and removing the second oxide material layer and the nitride material layer in the second region 100B, such that, the first oxide material layer remained in the second region 100B becomes the gate dielectric material layer 218, and the first oxide material layer, the nitride material layer, and the second oxide material layer together form the dielectric layer 110 as shown in FIG. 3. Otherwise, the gate dielectric material layer 218 may also be additionally formed in the second region 100B, after completely removing the second oxide material layer, the nitride material layer and the first oxide material layer in the second region 100B.

Further in view of FIG. 3, a first semiconductor material layer 252 is formed on the top surface of the dielectric layer 110 in the first region 100A, and on the top surface of the gate dielectric material layer 218 in the second region 100B, with the first semiconductor material layer 252 for example including a semiconductor material like doped polysilicon or doped amorphous silicon, but not limited thereto. It is noted that, since the first semiconductor material layer 252 is formed on the gate dielectric material layer 218 within the second region 100B, while the first semiconductor material layer 252 is formed on the dielectric layer 110 (including the ONO structure) within the first region 100A, the top surface of the first semiconductor material layer 252 within the second region 100B is not coplanar with the first semiconductor material layer 252 within the first region 100A. Then, a hard mask layer HM1 is formed within the second region 100B, entirely overlaying the first semiconductor material layer 252 in the second region 100B.

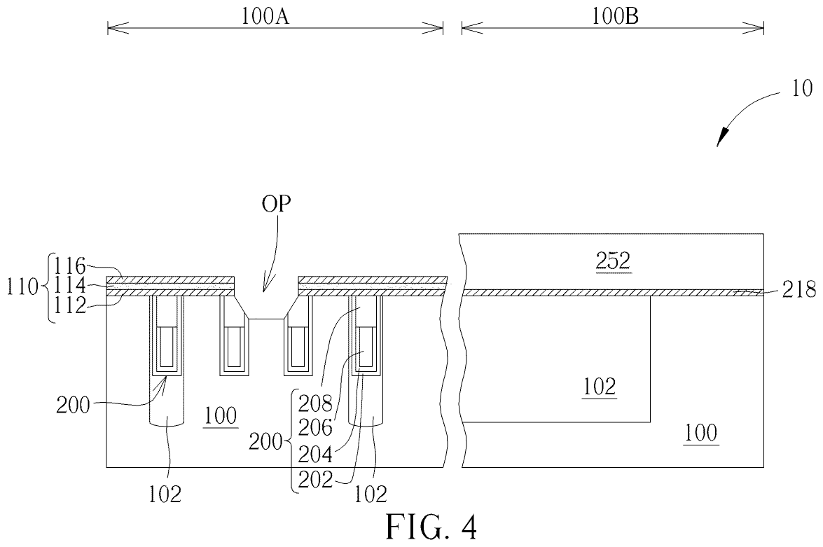

As shown in FIG. 4, an etching process is performed through the hard mask layer HM1 as shown in FIG. 3, completely removing the first semiconductor material layer 252 formed within the first region 100A, followed by completely removing the hard mask layer HM1. That is, after performing the etching process, only the first semiconductor material layer 252 formed over the gate dielectric material layer 218 is remained. Next, another etching process is performed through another hard mask layer (not shown in the drawings), partially removing the dielectric layer 110 and a portion of the substrate 100 underneath in the first region 100A, to form an opening OP between any two adjacent ones of the buried gate structures 200 for defining the formation positions of the bit line contact 132 as shown in FIG. 1. Then, the another hard mask layer is completely removed after forming the opening OP.

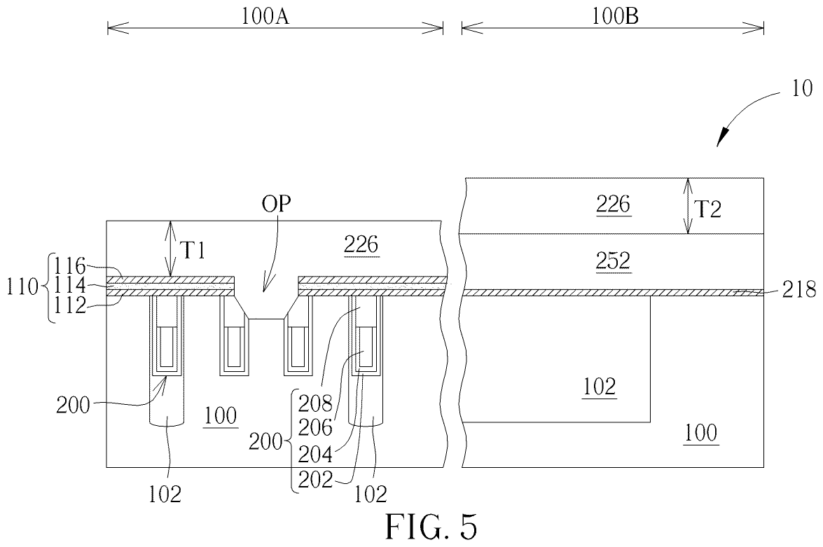

As shown in FIG. 5, a second semiconductor material layer 226 is simultaneously formed in the first region 100A and in the second region 100B, with the second semiconductor material layer 226 formed in the first region 100A filling in the opening OP and further covering on the dielectric layer 110, and with the second semiconductor material layer 226 formed within the second region 100B directly overlaying the first semiconductor material layer 252. The second semiconductor material layer 226 for example includes a semiconductor material like doped polysilicon or doped amorphous silicon, and preferably includes the same semiconductor material as the first semiconductor material layer 252, but not limited thereto. It is noted that, since the second semiconductor material layer 226 is formed on the dielectric layer 110 in the first region 100A, while the second semiconductor material layer 226 is formed on the first semiconductor material layer 252 within the second region 100B, the top surface of the second semiconductor material layer 226 within the first region 100A is not coplanar with the second semiconductor material layer 226 within the second region 100B. In one embodiment, the second semiconductor material layer 226 formed on the dielectric layer 110 for example includes the thickness T1, the second semiconductor material layer 226 formed on the first semiconductor material layer 252 for example includes the thickness T2 and a relative higher top surface, and the thickness T1 is preferably the same as the thickness T2, but not limited thereto.

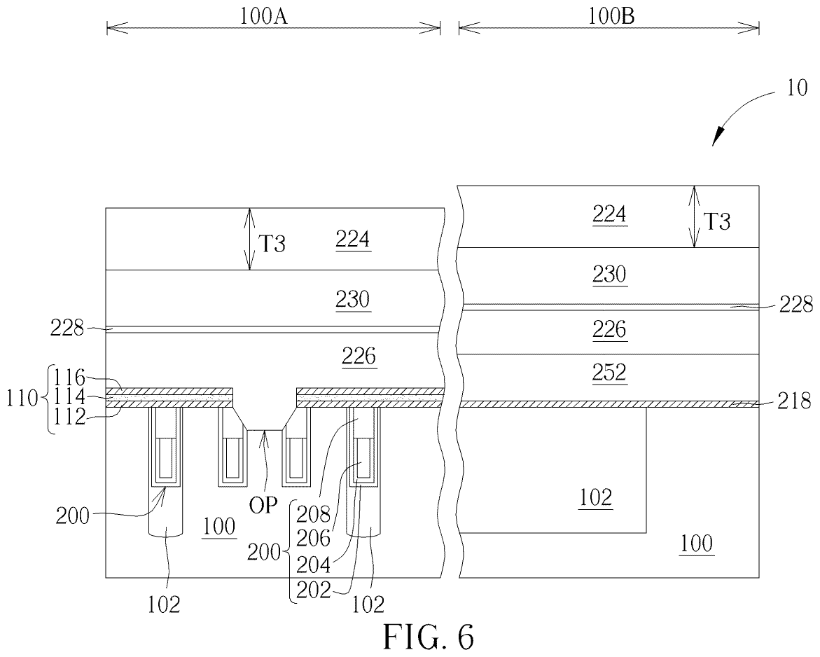

As shown in FIG. 6, a barrier material layer 228 (for example including a conductive barrier material such as titanium and/or titanium nitride), a metal material layer 230 (for example including a low-resistant conductive material like copper, aluminum, or tungsten) and a covering material layer 224 (for example including an insulating material like silicon oxide, silicon nitride or silicon oxynitride) stacked in sequence from bottom to top are simultaneously formed in the first region 100A and in the second region 100B, completely overlaying the second semiconductor material layer 226 formed within the first region 100A and the second region 100B. It is noted that, since the first semiconductor material layer 252 is additionally formed in the second region 100B, top surfaces of the barrier material layer 228, the top surfaces of each of the metal material layer 230 and the covering material layer 224 respective in the first region 100A and the second region 100B are not coplanar with each other.

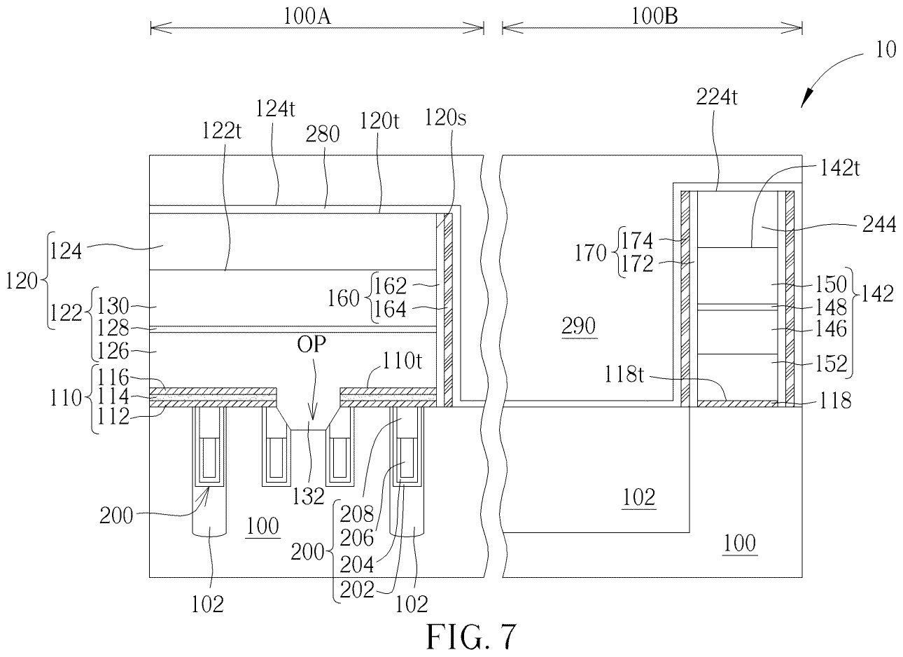

As shown in FIG. 7, a patterning process is simultaneously performed on the covering material layer 224, the metal material layer 230, the barrier material layer 228, the second semiconductor material layer 226, the first semiconductor material layer 252, and the dielectric layer 110 in the first region 100A and in the second region 100B, to form the semiconductor layer 126, the barrier layer 128, the metal layer 130 and the first cover layer 124 stacked in sequence on the top surface 110t of the dielectric layer 110 in the first region 100A, and also to form the gate dielectric layer 118, the bottom semiconductor layer 152, the top semiconductor layer 146, the barrier layer 148, the metal layer 150 and the covering material layer 224 stacked in sequence in the second region 100B. Accordingly, the semiconductor layer 126, the barrier layer 128 and the metal layer 130 stacked in sequence together form the first conductive layer 122, and the first conductive layer 122 and the first cover layer 124 will together form the bit line structure 120. Also, the semiconductor layer 126 filled in the opening OP will form the bit line contact 132, with the bit line contact 132 being monolithic with the semiconductor layer 126 of the bit line structure 120. On the other hand, the bottom semiconductor layer 152, the top semiconductor layer 146, the barrier layer 148 and the metal layer 150 stacked in sequence in the second region 100B together form the second conductive layer 142, and the covering material layer 224 still overlays the second conductive layer 142. Then, the top surface 142t of the second conductive layer 142 in the second region 100B is higher than the top surface 122t of the first conductive layer 122 in the first region 100A, and the top surface 224t of the covering material layer 224 in the second region 100B is higher than the top surface 124t (namely, the top surface 120t of the bit line structure 120) of the first cover layer 124 in the first region 100A.

Next, the bit line spacer 160 is formed on the sidewall 120s of the bit line structure 120 in the first region 100A, and the gate spacer 170 is formed on the sidewalls of the second conductive layer 142 and the covering material layer 224 in the second region 100B. In one embodiment, the formations of the bit line spacer 160 and the gate spacer 170 include but not limited to the following steps. Firstly, a first spacer material layer (for example including a material like silicon nitride or silicon carbonitride) and a second spacer material layer (for example including a material like silicon oxide or silicon oxynitride) are sequentially formed through the same deposition processes, entirely overlaying the bit line structure 120 in the first region 100A and the second conductive layer 142 and the covering material layer 224 in the second region 100B, and two etching back processes are respectively performed on the first spacer material layer and the second material layer, to form the spacer 162 and the spacer 164 stacked in sequence on the sidewall 120s of the bit line structure 120, and also, to form the spacer 172 and the spacer 174 stacked in sequence on the sidewall of the second conductive layer 142 and the covering material layer 224. The spacer 162 and the spacer 164 stacked in sequence on the sidewall 120s of the bit line structure 120 together form the bit line spacer 160, and the spacer 172 and the spacer 174 stacked in sequence on the sidewall of the second conductive layer 142 together form the gate spacer 170. In this way, the spacer 162 of the bit line spacer 160 and the spacer 172 of the gate spacer 170 preferably include the same material and the same thickness, and the spacer 172 of the gate spacer 170 and the spacer 174 of the gate spacer 170 preferably include the same material and the thickness, but not limited thereto.

Further in view of FIG. 7, an etching stop material layer 280 and an insulating material layer 290 are formed both within the first region 100A and the second region 100B, with both of the etching stop material layer 280 and the insulating material layer 290 entirely overlaying the bit line structure 120 in the first region 100A and the second conductive layer 142 and the covering material layer 224 in the second region 100B. It is noted that since a bottom semiconductor layer 152 is additionally formed in the second region 100B, the top surface of the etching stop material layer 280 formed in the first region 100A is not coplanar with the top surface of the etching stop material layer 280 formed in the second region 100B, with the top surface of the etching stop material layer 280 formed in the second region 100B being higher than the top surface of the etching stop material layer 280 formed in the first region 100A.

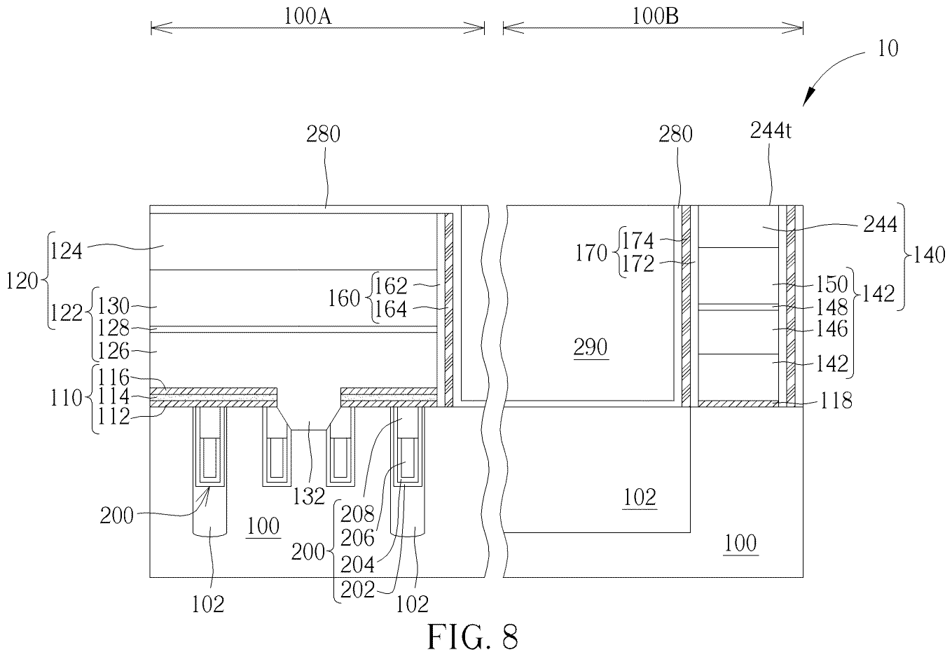

As shown in FIG. 8, a planarization process is performed to partially remove the insulating material layer 290 formed in the first region 100A and the second region 100B, and to partially remove the etching stop material layer 280 formed in the second region 100B, thereby exposing the top surface 224t of the covering material layer 244. It is noted that since the first region 100A includes the relative higher component-integrity, the planarization process is performed by using the etching stop material layer 280 formed within the first region 100A as a stop layer, removing the etching stop material layer 280 with the relative lower component-integrity in the second region 100B. Accordingly, after the planarization process is performed, the top surfaces of the insulating material layer 290 formed in the first region 100A and the second region 100B will be coplanar with each other, and also, the top surfaces of the etching stop material layer 280 formed in the first region 100A and the second region 100B will be coplanar with each other.

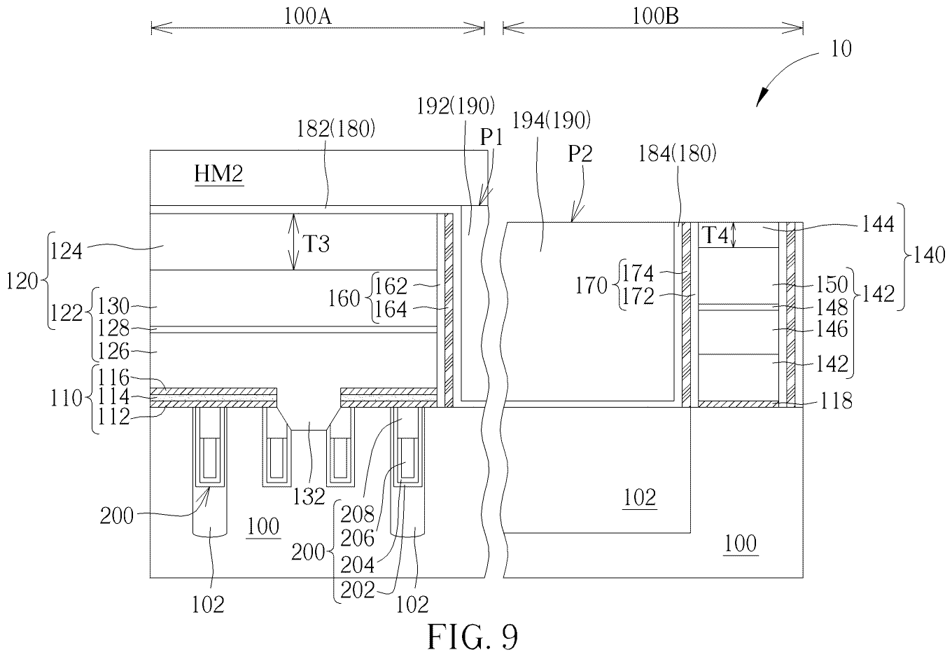

As shown in FIG. 9, a hard mask layer HM2 is formed in the first region 100A, and an etching back process is performed through the hard mask layer HM2, to partially remove the insulating material layer 290, the etching stop material layer 280, the gate spacer 170, and the covering material layer 224 in the second region 100B, and the insulating layer 194, the etching stop layer 184, the gate spacer 170 and the second cover layer 144 are formed thereby. The second cover layer 144 includes a relative smaller thickness T4. Accordingly, the second conductive layer 142 and the second cover layer 144 stacked in sequence on the second gate dielectric layer 118 will together form the gate structure 140. It is noted that, the insulating layer 194 formed within the second region 100B overlays the etching stop layer 184, to obtain the second plane P2 being coplanar with the top surface 140t of the gate structure 140 and the etching stop layer 184. On the other hand, after the etching back process is performed, the etching stop material layer 280 and the insulating material layer 290 formed in the first region 100A will respectively form the insulating layer 192 and the etching stop layer 182 at the same time.

Through these performances, the fabrications of the insulating layer 190 and the etching stop layer 180 as shown in FIG. 1 are accomplished, with the insulating layer 190 including the insulating layer 192 formed in the first region 100A and the insulating layer 194 formed in the second region 100B, and with the etching stop layer 180 including the etching stop layer 182 formed in the first region 100A and the etching stop layer 184 formed in the second region 100B. The insulating layer 192 includes the first plane P1 being coplanar with the top surface of the etching stop layer 180 covered on the top surface 120t of the bit line structure 120, and the insulating layer 194 includes the second plant P2 being coplanar with the top surface of the etching stop layer 184 and the top surface 140t of the gate structure 140. The first plane P1 is lower than the second plane P2. The etching stop layer 182 overlays the substrate 100, and the top surface 120t and the sidewall 120s of the bit line structure 120 in the first region 100A at the same time, and the etching stop layer 184 overlays the substrate 100, and the sidewall 140s of the gate structure 140 in the second region 100B.

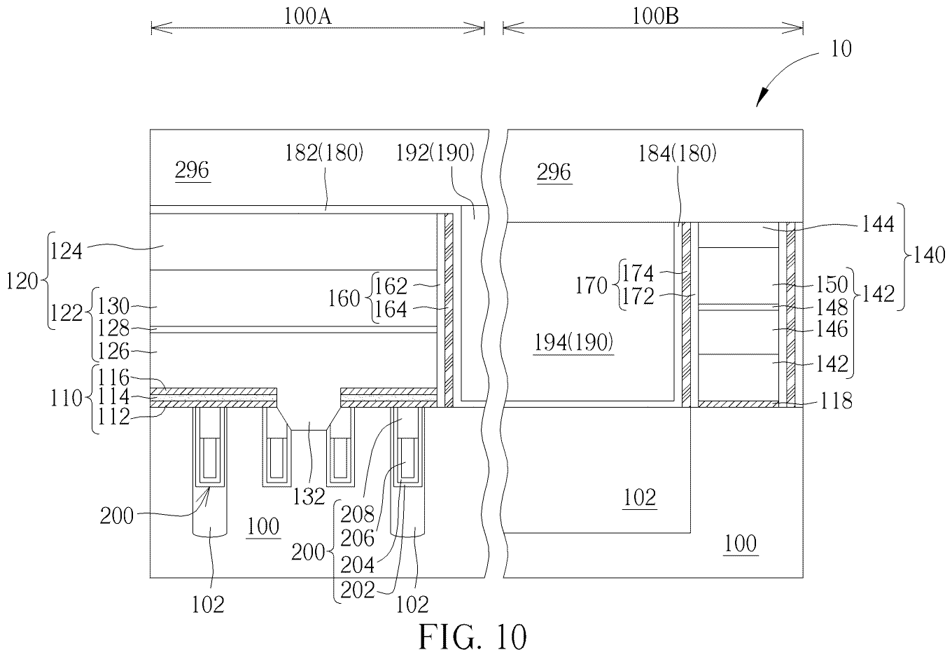

As shown in FIG. 10, the hard mask layer HM2 is removed, and an interlayer dielectric material layer 296 is formed both within the first region 100A and the second region 100B, entirely overlaying the insulating layer 192 and the top surface of the etching stop layer 182 in the first region 100A, and the insulating layer 194, the etching stop layer 184 and the top surfaces of the gate spacer 170 and the gate structure 140 in the second region 100B. Accordingly, the top surface of the interlayer dielectric material layer 296 in the first region 100A is coplanar with the top surface of the interlayer dielectric material layer 296 in the second region 100B. Subsequently, an etching back process is performed through the interlayer dielectric material layer 296 as shown in FIG. 10, to form the interlayer dielectric layer 196 as shown in FIG. 1. Then, the fabrication of the semiconductor device 10 in the present embodiment is accomplished.

According to the fabricating method of the semiconductor device 10 in the present embodiment, the bottom semiconductor layer 152 is additionally formed in the second region 100B, and the second conductive layer 142 will therefore obtain a relative higher top surface 142t, and the covering material layer 244 disposed on the second conductive layer 142 will also obtain a relative higher top surface 244t. Then, while forming the insulating layer 194 and the etching stop layer 184 in the second region 100B, the thickness T3 of the covering material layer 244 is thinned down to form the second cover layer 144 with the relative smaller thickness T4. Accordingly, the top surface 140t of the gate structure 140 formed within the second region 100B is correspondingly lower than the top surface 120t of the bit line structure 120, and the interlayer dielectric layer 196 formed subsequently enables to physically contact the top surface 140t of the gate structure 140, as well as the etching stop layer 182 covered on the top surface 120t of the bit line structure 120. In this way, the bit line structure 120 and the gate structure 140 respectively formed within the first region 100A and within the second region 100B are both obtain better structural reliability, such that the semiconductor device 10 of the present embodiment will gain the improved function and performance thereby.

Furthermore, people in the art shall easily realize that the method of fabricating the same in the present disclosure are not limited to the aforementioned embodiment, and may include other examples. The following description will detail the different embodiments of the fabricating method of semiconductor device in the present invention. To simplify the description, the following description will detail the dissimilarities among the different embodiments and the identical features will not be redundantly described. In order to compare the differences between the embodiments easily, the identical components in each of the following embodiments are marked with identical symbols.

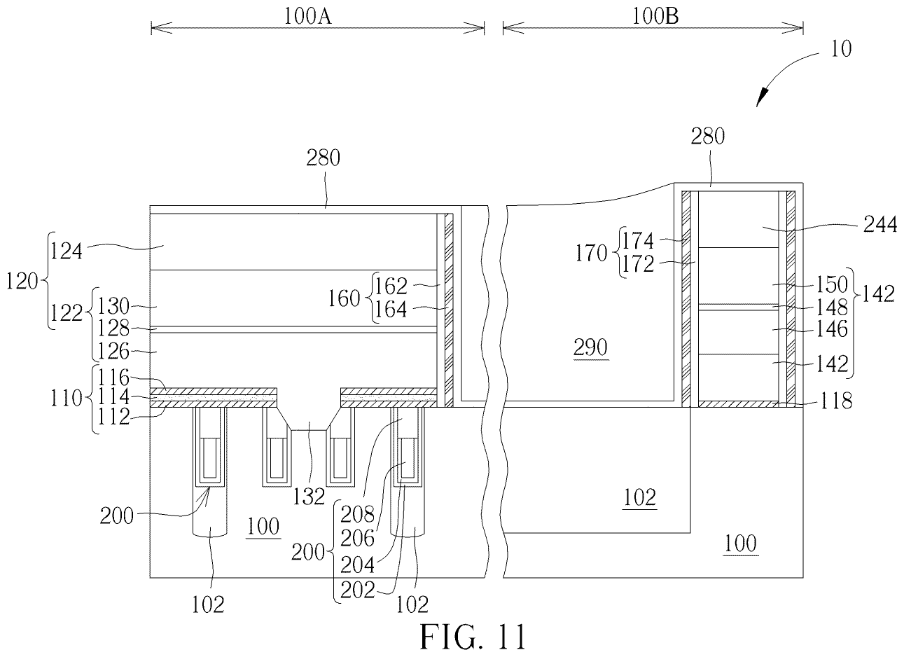

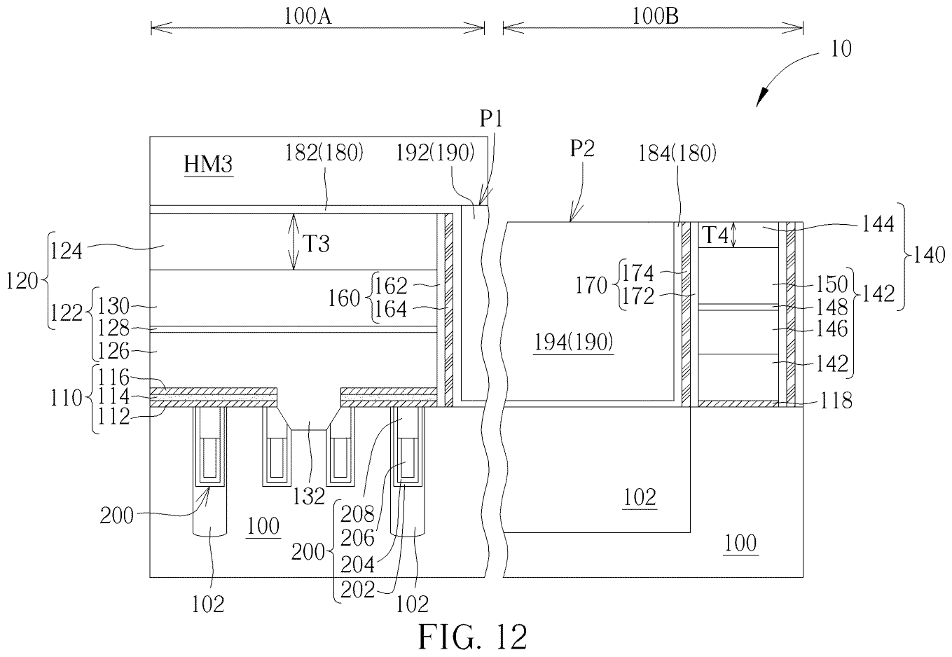

Please refer to FIG. 11 to FIG. 12, which illustrate schematic diagrams of a fabricating method of the semiconductor device 10 according to another preferable embodiment in the present disclosure. The formal fabricating processes of the present embodiment are substantially the same or similar to those in the aforementioned embodiment, and those steps will not be redundantly described herein. The difference between the present embodiment and the aforementioned embodiment is in that while performing the planarization process as shown in FIG. 8 in the present embodiment, the etching stop material layer 280 at a relative higher position in the second region 100B is used as an etching stop layer.

Precisely speaking, as shown in FIG. 11, while the planarization process is performed, the insulating material layer 290 in the second region 100B is partially removed till being coplanar with the etching stop material layer 280 in the second region 100B. Following these, the insulating material layer 290 in the second region 100B is excessive etched till forming a recessed top surface, and the insulating material layer 290 in the first region 100A is removed till exposing the etching stop material layer 280 in the first region 100A. In other words, the etching stop material layer 290 covered on the top surface 244t of the covering material layer 244 is not removed during the planarization process of the present embodiment, such that, after the planarization process, the insulating material layer 290 in the second region 100B has the recessed top surface, and the top surface of the etching stop material layer 280 in the first region 100A is coplanar with the top surface of the etching stop material layer 280 in the second region 100B.

As shown in FIG. 12, a hard mask layer HM3 is formed in the first region 100A, and an etching back process is performed through the hard mask layer HM3, to partially remove the insulating material layer 290, etching stop material layer 280, the gate spacer 170, and the covering material layer 244 in the second region 100B, to form the insulating layer 194, the etching stop layer 184, the gate spacer 170 and the second cover layer 144 in the second region 100B at the same time. The second cover layer 144 includes a relative smaller thickness T4. Then, the second conductive layer 142 and the second cover layer 144 stacked in sequence on the gate dielectric layer 118 together form the gate structure 140, and the insulating layer 194 formed within the second region 100B includes the second plane P2 being coplanar with the etching stop layer 184 and the top surface 140t of the gate structure 140. On the other hand, after the etching back process, the etching stop material layer 280 and the insulating material layer 292 formed within the first region 100A will therefore become the insulating layer 192 and the etching stop layer 182, with the insulating layer 192 obtaining the first plane P1 which is lower than the second plane P2.

After that, as shown in FIG. 10 of the aforementioned embodiment, the interlayer dielectric material layer 296 is formed both within the first region 100A and the second region 100B, and the etching process is performed to partially removed the interlayer dielectric material layer 296, to form the interlayer dielectric layer 196 as shown in FIG. 1. Through these performances above, the fabrication of semiconductor device 10 is also accomplished.

Overall speaking, according to the semiconductor device and the fabricating method thereof, an etching stop layer is formed to have various covering degrees within different regions, and/or a process such as a planarization process or an etching back process is additionally performed to thin down the thickness of a cover layer within a specific region, thereby reducing the possible height-difference between various regions of the semiconductor device, and also improving the structural reliability of the components. Accordingly, the components formed subsequently such as a memory cell is allowable to be formed on a flat plane, such that, the semiconductor device will therefore gain better performance and operation thereby.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, comprising a first region and a second region;
a bit line structure, disposed on the substrate and within the first region;
a gate structure, disposed on the substrate and within the second region;
an etching stop layer, disposed on the substrate and overlaying a top surface and a sidewall of the bit line structure, and a sidewall of the gate structure; and
an interlayer dielectric layer, disposed on the etching stop layer and the gate structure, wherein the interlayer dielectric layer physically contacts the etching stop layer covered on the top surface of the bit line structure, and a top surface of the gate structure, the bit line structure further comprises a first conductive layer and a first cover layer disposed in sequence, and the gate structure further comprises a second conductive layer and a second cover layer disposed in sequence, a thickness of the first cover layer is larger than a thickness of the second cover layer, and a bottommost surface of the first cover layer is lower than a bottommost surface of the second cover layer.

2. The semiconductor device according to claim 1, further comprising:
an insulating layer, disposed on the substrate and between the bit line structure and the gate structure, wherein the insulating layer comprising a first plane disposed within the first region and a second plane disposed within the second region, and the first plane is higher than the second plane.

3. The semiconductor device according to claim 1, wherein a top surface of the second conductive layer is higher than a top surface of the first conductive layer.

4. The semiconductor device according to claim 1, wherein a top surface of the second cover layer is lower than a top surface of the first cover layer.

5. The semiconductor device according to claim 1, wherein the first conductive layer comprises a semiconductor layer, a barrier layer and a metal layer stacked in sequence, the second conductive layer comprises a bottom semiconductor layer, a top semiconductor layer, a barrier layer and a metal layer stacked in sequence, and a top surface of the semiconductor layer of the first conductive layer is higher than a top surface of the bottom semiconductor layer of the second conductive layer.

6. The semiconductor device according to claim 5, further comprising:
at least one bit line contact, disposed under the bit line structure and partially extended into the substrate, wherein the semiconductor layer of the first conductive layer and the at least one bit line contact are monolithic.

7. The semiconductor device according to claim 1, further comprising:
a bit line spacer, disposed on a sidewall of the bit line structure, between the bit line structure and the etching stop layer that overlays the bit line structure; and
a gate spacer, disposed on a sidewall of the gate structure, between the gate structure, and the etching stop layer that overlays the sidewall of the gate structure.

8. The semiconductor device according to claim 7, wherein the etching stop layer that overlays the bit line structure physically contacts a top surface of the bit line spacer.

9. A method of fabricating a semiconductor device, comprising:
providing a substrate, the substrate comprising a first region and a second region;
forming a bit line structure on the substrate, within the first region;
forming a gate structure on the substrate, within the second region;
forming an etching stop layer, overlaying a top surface and a sidewall of the bit line structure, and a sidewall of the gate structure; and
forming an interlayer dielectric layer, overlaying the etching stop layer and the gate structure, wherein the interlayer dielectric layer physically contacts the etching stop layer that overlays the top surface of the bit line structure, and a top surface of the gate structure.

10. The method of fabricating the semiconductor device according to claim 9, further comprising:
forming an etching stop material layer, entirely overlaying the bit line structure and the gate structure; and
forming an insulating material layer on the substrate, overlaying the etching stop material layer and being partially between the bit line structure and the gate structure.

11. The method of fabricating the semiconductor device according to claim 10, further comprising:
performing a planarization process, removing the insulating material layer overlaying top surfaces of the gate structure and the bit line structure.

12. The method of fabricating the semiconductor device according to claim 11, while performing a planarization process, removing the insulating material layer overlaying top surfaces of the gate structure and the bit line structure.

13. The method of fabricating the semiconductor device according to claim 11, forming the gate structure and the bit line structure further comprising:
sequentially forming a first conductive layer and a first cover layer on the substrate, within the first region;
sequentially forming a second conductive layer and a covering material layer, within the second region, wherein the covering material layer and the first cover layer comprise a same thickness, and a top surface of the covering material layer is higher than a top surface of the first cover layer; and
performing an etching back process, partially removing the insulating material layer and the covering material layer within the second region to form an insulating layer and a second cover layer, wherein a top surface of the second cover layer is lower than the top surface of the first cover layer.

14. The method of fabricating the semiconductor device according to claim 13, wherein the insulating layer comprises a first plane formed within the first region and a second plane formed within the second region, and the first plane is higher than the second plane.

15. The method of fabricating the semiconductor device according to claim 13, after performing an etching back process, a thickness of the first cover layer is larger than a thickness of the second cover layer, and a bottommost surface of the first cover layer is lower than a bottommost surface of the second cover layer.

16. The method of fabricating the semiconductor device according to claim 13, wherein while performing the etching back process, simultaneously removing the etching stop material layer overlaying the top surface of the gate structure to form the etching stop layer.

17. The method of fabricating the semiconductor device according to claim 9, further comprising:
forming a bit line spacer on the sidewall of the bit line structure, between the bit line structure, and the etching stop layer overlaying the bit line structure; and
forming a gate spacer on the sidewall of the gate structure, between the gate structure, and the etching stop layer overlaying the sidewall of the gate structure.
